(19) United States
(12) Patent Application Publication
(10) Pub. No.: US 2015/0263020 A1
(43) Pub. Date: Sep. 17, 2015

(54) SEMICONDUCTOR DEVICE AND METHOD OF MANUFACTURING THE SAME

(71) Applicant: Semiconductor Manufacturing International (Shanghai) Corporation, Shanghai (CN)

(72) Inventors: Xiaoyuan WANG, Shanghai (CN); Chuanmiao ZHOU, Shanghai (CN); Fengji JIN, Shanghai (CN); Hongwei LI, Shanghai (CN); Bing GUO, Shanghai (CN); Zhiguang GUO, Shanghai (CN)

(21) Appl. No.: 14/611,866

(22) Filed: Feb. 2, 2015

(30) Foreign Application Priority Data
Mar. 11, 2014 (CN) 201410088289.7

(51) Int. Cl. H01L 27/115; H01L 21/8238; H01L 27/02

(52) U.S. Cl. CPC H01L 27/11526; H01L 27/0266; H01L 21/823857

(57) ABSTRACT

A semiconductor device is provided. The semiconductor device includes a semiconductor substrate and an electrostatic discharge (ESD) protection device disposed on the semiconductor substrate. The ESD protection device includes a source and a drain disposed in the semiconductor substrate, a gate disposed on the semiconductor substrate between the source and the drain, and a p-type doped region disposed in the drain.

### CROSS-REFERENCE TO RELATED APPLICATION

This application claims priority to Chinese Patent Application No. 201410088289.7 filed on Mar. 11, 2014, the disclosure of which is incorporated herein by reference in its entirety.

### BACKGROUND

1. Technical Field

The present disclosure relates to the field of semiconductor technology, and more particularly to a semiconductor device and a method of manufacturing the same.

2. Description of the Related Art

In the field of semiconductor technology, electrically erasable programmable read-only memory (EEPROM) is a type of non-volatile storage device that is widely used in computers, mobile phones and other electronic devices.

Electrostatic discharge (ESD) protection is necessary to protect the EEPROM since the EEPROM and other semiconductor devices are often operated in different environments and under various conditions. In a conventional EEPROM, a high-voltage n-type metal-oxide-semiconductor (NMOS) with a rated working voltage of 5V is typically employed as an ESD protection device. However, conventional ESD protection devices often fail to provide adequate ESD protection for the EEPROM.

The high-voltage NMOS may be unable to meet the ESD protection requirements under certain conditions. The actual value of the trigger voltage in the high-voltage NMOS (in a conventional ESD protection device) usually exceeds the design value of the trigger voltage. For example, the actual value of the trigger voltage is usually around 14 V, whereas the design value of the trigger voltage is usually designated to be 10 V. Therefore, when the static electricity is greater than 10 V and less than 14 V, the high-voltage NMOS of the ESD protection device is not activated since the actual value of the trigger voltage has not yet been met. As a result, electrostatic damage to the EEPROM may occur under the above conditions.

### SUMMARY

The present disclosure addresses at least the above issues in the prior art.

According to an embodiment of the inventive concept, a semiconductor device is provided. The semiconductor device includes a semiconductor substrate and an electrostatic discharge (ESD) protection device disposed on the semiconductor substrate. The ESD protection device includes a source and a drain disposed in the semiconductor substrate, a gate disposed on the semiconductor substrate between the source and the drain, and a p-type doped region disposed in the drain.

In one embodiment, the source and the drain may be n+ doped.

In one embodiment, the gate may be made of polysilicon.

In one embodiment, the semiconductor device may further include metal silicide formed on the source, the drain, and the gate.

In one embodiment, the ESD protection device may be an NMOS device.

In one embodiment, the semiconductor device may further include a cell, wherein the ESD protection device is configured to prevent ESD damage to the cell.

In one embodiment, the semiconductor device may be an electrically erasable programmable read-only memory (EEPROM).

According to another embodiment of the inventive concept, a method of manufacturing a semiconductor device is provided. The method includes: providing a semiconductor substrate; forming a high-voltage n-type metal-oxide-semiconductor (NMOS) on the semiconductor substrate, wherein the high-voltage NMOS serves as an electrostatic discharge (ESD) protection device and includes a source, a drain, and a gate; performing p+ ion implantation on the drain of the high-voltage NMOS, so as to form a p-type doped region in the drain; and forming a dielectric layer over the semiconductor substrate, and forming at least one contact hole through the dielectric layer.

In one embodiment, the method may further include: forming a high-voltage p-type metal-oxide-semiconductor (PMOS), a low-voltage NMOS, and a low-voltage PMOS; defining a source region on the semiconductor substrate, and performing ion implantation on a channel region; forming a well region of the high-voltage PMOS; forming a gate oxide layer; forming a high-voltage gate and a floating gate; forming a well region of the low-voltage NMOS and a well region of the low-voltage PMOS; forming a dielectric layer on the floating gate and a control gate on the dielectric layer; forming a low-voltage gate; performing lightly doped drain (LDD) processing on the high-voltage NMOS, the high-voltage PMOS, the low-voltage NMOS, and the low-voltage PMOS; and forming the source and the drain of the high-voltage NMOS.

In one embodiment, the method may further include: adjusting a threshold voltage of the high-voltage NMOS.

In one embodiment, the source and the drain of the high-voltage NMOS may be n+ doped.

In one embodiment, the gate of the high-voltage NMOS may be made of polysilicon.

In one embodiment, the method may further include: forming metal silicide on the source, the drain, and the gate.

In one embodiment, the semiconductor device may be an electrically erasable programmable read-only memory (EEPROM).

### BRIEF DESCRIPTION OF THE DRAWINGS

The accompanying drawings, which are incorporated herein and constitute a part of the specification, illustrate different embodiments of the inventive concept and, together with the detailed description, serve to describe more clearly the inventive concept.

It is noted that in the accompanying drawings, for convenience of description, the dimensions of the components shown may not be drawn to scale. Also, same or similar reference numbers between different drawings represent the same or similar components.

FIG. 1 depicts a schematic cross-sectional view of an ESD protection device in a semiconductor device.

FIG. 2 depicts a schematic cross-sectional view of an ESD protection device in a semiconductor device according to an embodiment.

FIG. 3A is a graph of the transmission line pulse (TLP) test results of an ESD protection device in an EEPROM according to the prior art.

FIG. 3B is a graph of the TLP test results of an ESD protection device in a semiconductor device according to an embodiment.

FIG. 4 is a flowchart illustrating a method of manufacturing a semiconductor device according to an embodiment.

FIG. 5 is a flowchart illustrating a method of manufacturing a semiconductor device according to another embodiment.

### DETAILED DESCRIPTION

Various embodiments of the inventive concept are next described in detail with reference to the accompanying drawings. It is noted that the following description of the different embodiments is merely illustrative in nature, and is not intended to limit the inventive concept, its application, or use. The relative arrangement of the components and steps, and the numerical expressions and the numerical values set forth in these embodiments do not limit the scope of the inventive concept unless otherwise specifically stated. In addition, techniques, methods, and devices as known by those skilled in the art, although omitted in some instances, are intended to be part of the specification where appropriate. It should be noted that for convenience of description, the sizes of the elements in the drawings may not be drawn to scale.

In the drawings, the sizes and/or relative sizes of layers and regions may be exaggerated for clarity. Like reference numerals denote the same elements throughout.

It should be understood that when an element or layer is referred to as “in”, “adjacent to”, “connected to”, or “coupled to” another element or layer, it can be directly on the other element or layer, adjacent, connected or coupled to the other element or layer. In some instances, one or more intervening elements or layers may be present. In contrast, when an element is referred to as being “directly on”, “directly adjacent to”, “directly connected to”, or “directly coupled to” another element or layer, there are no intervening elements present or layer. It will be understood that, although the terms “first,” “second,” “third,” etc. may be used herein to describe various elements, the elements should not be limited by those terms. Instead, those terms are merely used to distinguish one element from another. Thus, a “first” element discussed below could be termed a “second” element without departing from the teachings of the present inventive concept. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's spatial relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments and is not intended to limit the inventive concept. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art, and should not be interpreted in an idealized or overly formal sense unless expressly so defined herein.

Exemplary embodiments are described herein with reference to cross-sectional illustrations that are schematic illustrations of idealized exemplary embodiments (and intermediate structures) of the inventive concept. As such, variations from the shapes of the illustrations as a result of, for example, manufacturing techniques and/or tolerances, are to be expected. Thus, the exemplary embodiments should not be construed as being limited to the particular shapes of regions illustrated herein, but may also include deviations in shapes that result, for example, from manufacturing tolerances. The regions illustrated in the figures are schematic in nature, and their shapes are not intended to illustrate the actual shape of a region of a device, and should not be construed to limit the scope of the inventive concept.

It should be understood that the inventive concept is not limited to the embodiments described herein. Rather, the inventive concept may be modified in different ways to realize different embodiments.

A semiconductor device according to an embodiment of the inventive concept includes an ESD protection device that offers improved ESD protection compared to conventional ESD protection devices. The semiconductor device may be an EEPROM, and may also include other semiconductor devices including the exemplary ESD protection device.

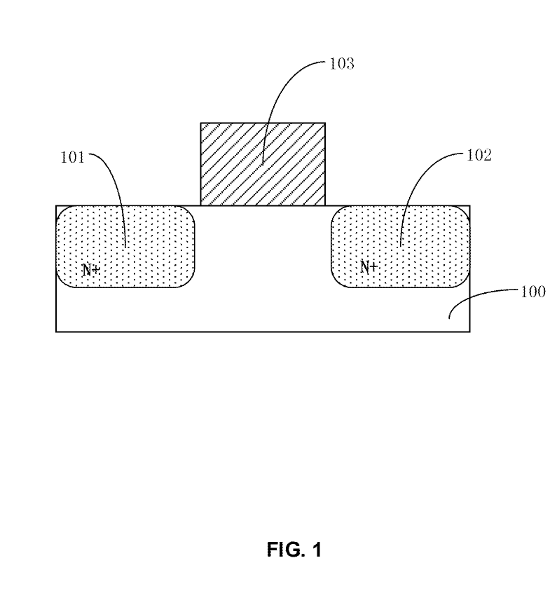

As previously mentioned in the Background section, a high-voltage n-type NMOS is typically employed as an ESD protection device. The structure of the high-voltage NMOS is illustrated in FIG. 1. As shown in FIG. 1, the high-voltage NMOS includes a semiconductor substrate 100. A source 101, a drain 102, and a gate 103 are disposed on the semiconductor substrate 100.

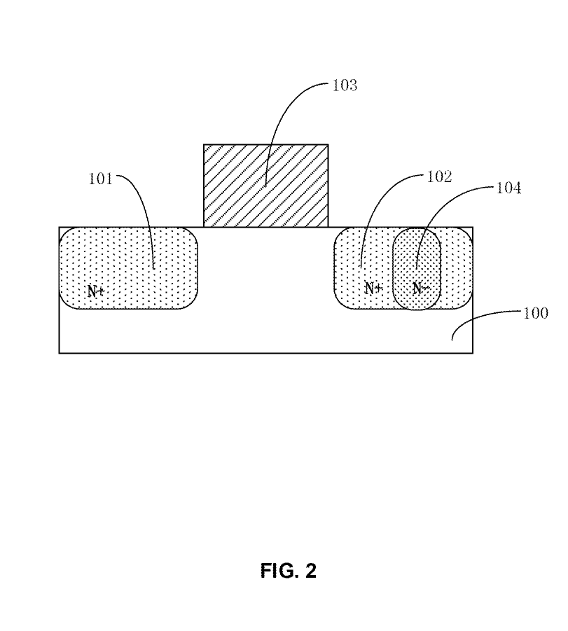

Next, a semiconductor device according to an embodiment will be described with reference to FIG. 2. The semiconductor device includes an ESD protection device. In some embodiments, the semiconductor device consists of the ESD protection device. In other embodiment, the semiconductor device includes the ESD protection device and other devices. Specifically, the ESD protection device can be used to protect other devices from damage due to electrostatic discharge.

Referring to FIG. 2, the ESD protection device includes a source 101 and a drain 102 disposed in a semiconductor substrate 100, and a gate 103 disposed on the semiconductor substrate 100 between the source 101 and the drain 102. The source 101 and the drain 102 may be n+ doped. The ESD protection device further includes a p-type doped region 104 (e.g. a p-well) disposed within the drain 102. Due to the combined effect of the n+ dopant (in the source 101 and the drain 102) and the p-type dopant (in the p-type doped region 104), the p-type doped region 104 actually becomes n− doped, as shown in FIG. 2. The gate 103 may be a polysilicon gate or a metal gate. In some embodiments (not shown), metal silicide may be formed on the source 101, the drain 102, and the gate 103, so as to reduce contact resistance.

In one embodiment (not shown), the semiconductor device further includes a cell disposed on the semiconductor substrate 100. The cell serves as a memory core in the semiconductor device and provides storage capability. The ESD protection device serves to protect the cell from ESD damage. In the above embodiment, the semiconductor device may be an EEPROM, and the ESD protection device may employ existing design rules for fabricating a high-voltage NMOS. However, the exemplary ESD protection device is different from a conventional high-voltage NMOS. Unlike the conventional high-voltage NMOS, an additional p-type well (e.g. a p-well) is formed in the drain of a high-voltage NMOS in the exemplary ESD protection device.

As previously mentioned, the ESD protection device in the exemplary semiconductor device is a type of NMOS. However, unlike a conventional NMOS, the ESD protection device in the exemplary semiconductor device includes the p-type doped region 104 in the drain 102. In particular, the p-type doped region 104 can improve the ESD protection capability of the ESD protection device in the exemplary semiconductor device.

Computer simulations may be performed for the exemplary ESD protection device, and the high-voltage NMOS (having a rated working voltage of 5V) in a conventional ESD protection device, respectively. Comparing the simulation results, it may be noted that in the conventional high-voltage NMOS, the breakdown point is located in a region beneath the gate. In contrast, in the exemplary ESD protection device, the breakdown point is located in a region between the drain and the substrate (drain-to-substrate area).

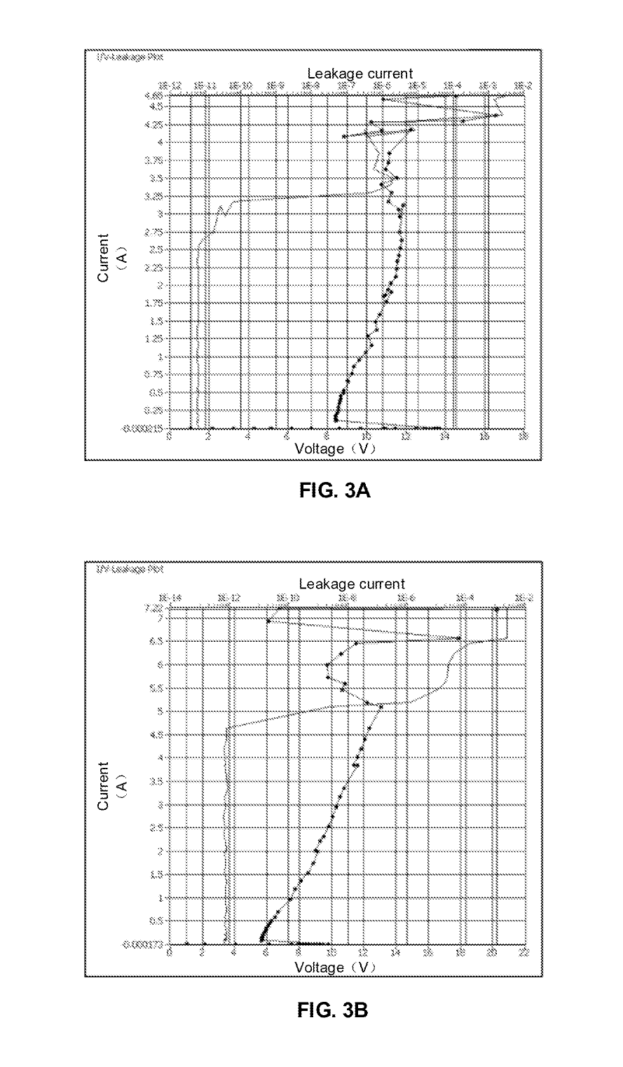

FIG. 3A is a graph of the transmission line pulse (TLP) test results of an ESD protection device in an EEPROM according to the prior art. FIG. 3B is a graph of the TLP test results of an ESD protection device in a semiconductor device according to an embodiment. Specifically, the TLP test results are presented in the form of current/voltage (IN) leakage curves. As shown in FIG. 3A, the actual value of the trigger voltage in a conventional ESD protection device is 14 V. In contrast, as shown in FIG. 3B, the actual trigger voltage of the exemplary ESD protection device is 10 V. Accordingly, the exemplary ESD protection device can meet design requirements since the design value of the trigger voltage is usually designated to be 10 V.

According to the above-described embodiments, ESD protection capability can be improved by including a p-type doped region in the drain of the ESD protection device, thereby further improving the reliability of the semiconductor device.

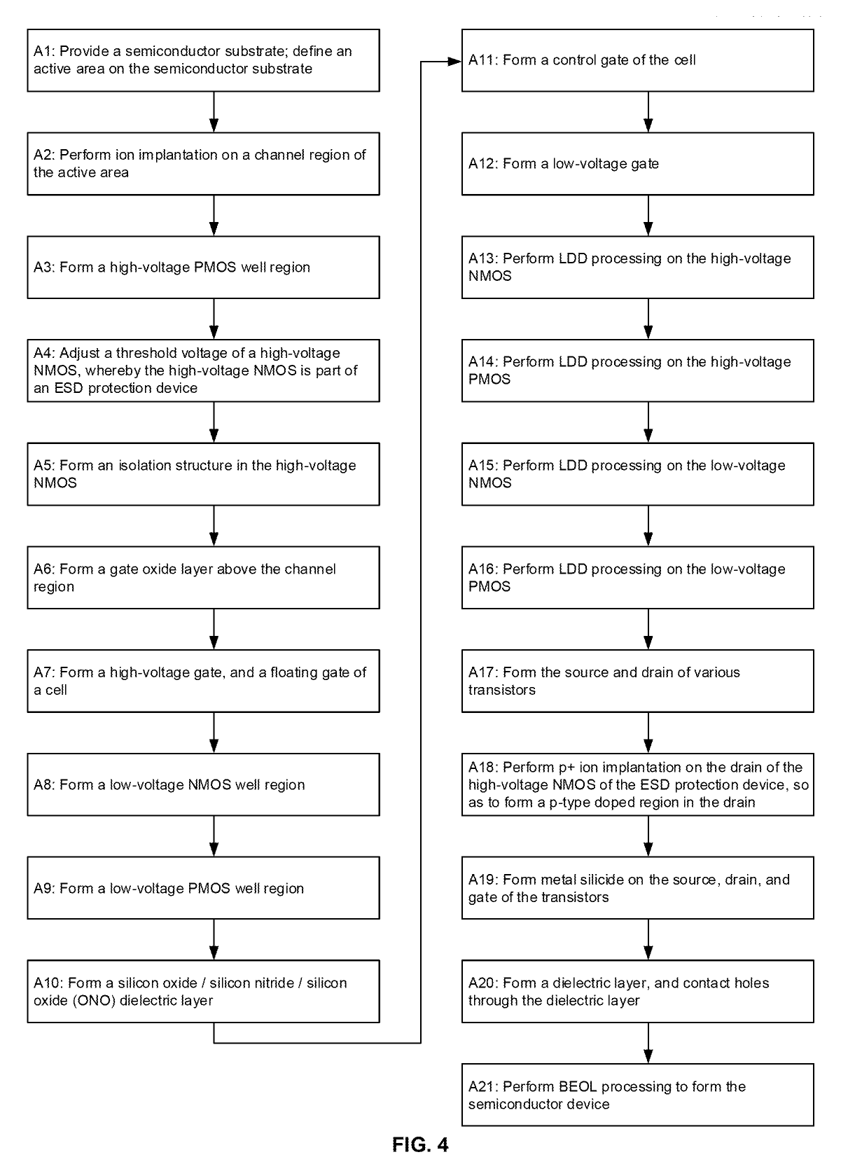

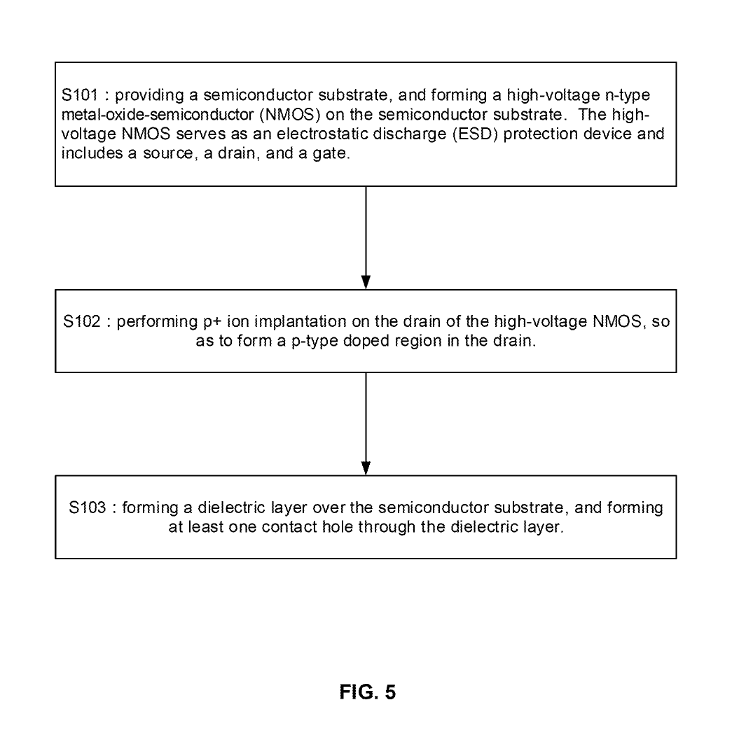

Next, a method of manufacturing a semiconductor device according to an embodiment will be described in detail with reference to FIG. 4. The method includes the following steps. Some or all of the following steps may be incorporated into the method of FIG. 5, as described later in the specification. Also, it should be noted that the sequence of steps may be modified by those skilled in the art.

In Step A1, a semiconductor substrate is provided. An active area is defined in the semiconductor substrate.

In Step A2, ion implantation is performed on a channel region of the active area.

In Step A3, a high-voltage PMOS well region is formed.

In Step A4, a threshold voltage of a high-voltage NMOS is adjusted. The high-voltage NMOS constitutes part of an ESD protection device.

In Step A5, an isolation structure is formed in the high-voltage NMOS. The isolation structure may include, for example, shallow trench isolation (STI) structures.

In Step A6, a gate oxide layer is formed above the channel region.

In Step A7, a high-voltage gate, and a floating gate of a cell, are formed. The high-voltage gate and the floating gate may be made of polysilicon or other appropriate materials. The floating gate of the cell primarily refers to the floating gate of a memory device.

In Step A8, a low-voltage NMOS well region is formed. In one embodiment, the rated working voltage of the low-voltage NMOS is 1.8 V.

In Step A9, a low-voltage PMOS well region is formed. In one embodiment, the rated working voltage of the low-voltage PMOS is 1.8 V.

In Step A10, a silicon oxide/silicon nitride/silicon oxide (ONO) dielectric layer is formed. The ONO dielectric layer is disposed on the floating gate of the memory device.

In Step A11, a control gate of the cell is formed. The control gate is disposed on the ONO dielectric layer.

In Step A12, a low-voltage gate is formed. The low-voltage gate may be made of polysilicon or other appropriate materials.

In Step A13, lightly doped drain (LDD) processing is performed on the high-voltage NMOS.

In Step A14, LDD processing is performed on the high-voltage PMOS.

In Step A15, LDD processing is performed on the low-voltage NMOS.

In Step A16, LDD processing is performed on the low-voltage PMOS.

In Step A17, the source and drain of various transistors are formed. In one embodiment, the source and drain may be formed by performing n+ ion implantation on the corresponding (source/drain) regions of the semiconductor substrate.

In Step A18, p+ ion implantation is performed on the drain of the high-voltage NMOS of the ESD protection device, so as to form a p-type doped region in the drain.

In Step A19, metal silicide is formed on the source, drain, and gate of the transistors.

In Step A20, a dielectric layer, and contact holes through the dielectric layer, are formed.

In Step A21, the resulting structure (after Step A20) undergoes back-end-of-line (BEOL) processing to form the semiconductor device. The semiconductor device may be, for example, an EEPROM.

A method of manufacturing a semiconductor device according to an embodiment has been described above with reference to Steps A1 through A21 and FIG. 4. However, the inventive concept is not limited to the above and may include additional semiconductor processing steps known to those skilled in the art. The additional steps may include forming dielectric layers and interconnects. Since the additional steps are known to those skilled in the art, a detailed description of those steps will be omitted. Furthermore, it should be noted that some of the above steps may be omitted or modified in various ways by those skilled in the art.

The above exemplary method for forming the semiconductor device differs from the prior art as follows. In the above exemplary method, forming the ESD protection device includes performing p+ ion implantation on the drain of the high-voltage NMOS, so as to form a p-type doped region in the drain.

A semiconductor device formed using the above exemplary method includes a p-type doped region in the drain of the NMOS of the ESD protection device. Accordingly, the ESD protection capability of the ESD protection device can be improved, thereby further improving the reliability of the semiconductor device.

FIG. 5 is a flowchart of a method for manufacturing a semiconductor device according to an embodiment. The method of FIG. 5 may include some or all of the previously-described Steps A1 through A21 in FIG. 4. Specifically, the method of FIG. 5 includes the following steps.

Step S101: providing a semiconductor substrate, and forming an NMOS of the ESD protection device on the semiconductor substrate, whereby the NMOS includes a source, a drain, and a gate.

Step S102: performing p+ ion implantation on the drain of the NMOS, so as to form a p-type doped region in the drain.

Step S103: forming a dielectric layer over the semiconductor substrate, and forming contact holes through the dielectric layer.

It is noted that the semiconductor device of FIG. 2, or a semiconductor device manufactured using the methods of FIGS. 4 and 5, may be incorporated into an electronic apparatus. As previously mentioned, the exemplary semiconductor devices have improved ESD protection capability and reliability compared to the semiconductor devices in the prior art. The exemplary semiconductor devices can be formed on an integrated circuit that is then incorporated into the electronic apparatus. The electronic apparatus may include mobile phones, tablet PCs, laptops, netbooks, game consoles, TVs, VCD players, DVD players, navigation systems, cameras, video cameras, voice recorders, MP3/MP4 players, PSPs, and any other electronic products or devices.

Embodiments of a semiconductor device and a method of manufacturing the semiconductor device have been described in the foregoing description. To avoid obscuring the inventive concept, details that are well-known in the art may have been omitted. Nevertheless, those skilled in the art would be able to understand the implementation of the inventive concept and its technical details in view of the present disclosure.

Different embodiments of the inventive concept have been described with reference to the accompanying drawings. However, the different embodiments are merely illustrative and are not intended to limit the scope of the inventive concept. Furthermore, those skilled in the art would appreciate that various modifications can be made to the different embodiments without departing from the scope of the inventive concept.

What is claimed is:

1. A semiconductor device comprising:
a semiconductor substrate; and
an electrostatic discharge (ESD) protection device disposed on the semiconductor substrate, wherein the ESD protection device comprises:
a source and a drain disposed in the semiconductor substrate;
a gate disposed on the semiconductor substrate between the source and the drain; and
a p-type doped region disposed in the drain.

2. The semiconductor device according to claim 1, wherein the source and the drain are n+ doped.

3. The semiconductor device according to claim 1, wherein the gate is made of polysilicon.

4. The semiconductor device according to claim 1, further comprising:
metal silicide formed on the source, the drain, and the gate.

5. The semiconductor device according to claim 1, wherein the ESD protection device is an NMOS device.

6. The semiconductor device according to claim 1, further comprising:
a cell, wherein the ESD protection device is configured to prevent ESD damage to the cell.

7. The semiconductor device according to claim 1, wherein the semiconductor device is an electrically erasable programmable read-only memory (EEPROM).

8. A method of manufacturing a semiconductor device, comprising:
providing a semiconductor substrate;
forming a high-voltage n-type metal-oxide-semiconductor (NMOS) on the semiconductor substrate, wherein the high-voltage NMOS serves as an electrostatic discharge (ESD) protection device and includes a source, a drain, and a gate;
performing p+ ion implantation on the drain of the high-voltage NMOS, so as to form a p-type doped region in the drain; and
forming a dielectric layer over the semiconductor substrate, and forming at least one contact hole through the dielectric layer.

9. The method according to claim 8, further comprising:
forming a high-voltage p-type metal-oxide-semiconductor (PMOS), a low-voltage NMOS, and a low-voltage PMOS;
defining a source region on the semiconductor substrate, and performing ion implantation on a channel region;
forming a well region of the high-voltage PMOS;
forming a gate oxide layer;
forming a high-voltage gate and a floating gate;
forming a well region of the low-voltage NMOS and a well region of the low-voltage PMOS;
forming a dielectric layer on the floating gate and a control gate on the dielectric layer;
forming a low-voltage gate;
performing lightly doped drain (LDD) processing on the high-voltage NMOS, the high-voltage PMOS, the low-voltage NMOS, and the low-voltage PMOS; and
forming the source and the drain of the high-voltage NMOS.

10. The method according to claim 9, further comprising:
adjusting a threshold voltage of the high-voltage NMOS.

11. The method according to claim 8, wherein the source and the drain of the high-voltage NMOS are n+ doped.

12. The method according to claim 8, wherein the gate of the high-voltage NMOS is made of polysilicon.

13. The method according to claim 8, further comprising:
forming metal silicide on the source, the drain, and the gate.

14. The method according to claim 8, wherein the semiconductor device is an electrically erasable programmable read-only memory (EEPROM).
